(19) United States
(12) Patent Application Publication
(10) Pub. No.: US 2013/0043523 A1
(43) Pub. Date: Feb. 21, 2013

(54) NONVOLATILE SEMICONDUCTOR MEMORY DEVICE AND METHOD OF MANUFACTURING THE SAME

(71) Applicants: Takahiko Ohno, Yokkaichi-shi (JP); Kenji Sawamura, Yokohama-shi (JP); Yasuhiro Shiino, Yokohama Shi (JP)

(72) Inventors: Takahiko Ohno, Yokkaichi-shi (JP); Kenji Sawamura, Yokohama-shi (JP); Yasuhiro Shiino, Yokohama Shi (JP)

(21) Appl. No.: 13/481,068

(22) Filed: May 25, 2012

(30) Foreign Application Priority Data
Aug. 19, 2011 (JP) 2011-179477

(51) Int. Cl. H01L 21/764; H01L 29/792

(52) U.S. Cl. 257/324; 438/591; 257/E29.309; 257/E21.21

(57) ABSTRACT

According to one embodiment, a nonvolatile semiconductor memory device includes a plurality of gate electrode structures formed on a semiconductor substrate and an insulating film which covers the gate electrode structures and has an air gap in it. Each of the gate electrode structures includes a gate insulting film, a charge storage layer, an intermediary insulating film, and a control gate electrode. The control gate electrode includes a first control gate and a second control gate whose width is greater than that of the first control gate. The air gap is formed so as to be higher than a space between the control gate electrodes and than the control gate electrodes.

### CROSS-REFERENCE TO RELATED APPLICATIONS

This application is based upon and claims the benefit of priority from prior Japanese Patent Application No. 2011-179477, filed Aug. 19, 2011, the entire contents of which are incorporated herein by reference.

### FIELD

Embodiments described herein relate generally to a nonvolatile semiconductor memory device, such as a NAND flash memory, and a method of manufacturing the same.

### BACKGROUND

A NAND flash memory has a gate electrode structure that has a charge storage layer, an intermediary insulating film, and a control gate constituting a word line. These are stacked on a gate insulating film formed on a silicon substrate.

In recent years, as memory elements have been miniaturized further, the interconnection resistance of control gates has increased and the coupling capacitance between memory elements has been getting higher, causing a delay in the propagation of a program voltage on a word line and a voltage drop, thereby decreasing reliability.

### BRIEF DESCRIPTION OF THE DRAWINGS

FIG. 1 is a sectional view of a nonvolatile semiconductor memory device according to a first embodiment;

FIGS. 2A, 2B, 2C, 2D, 2E are sectional views to explain a method of manufacturing a nonvolatile semiconductor memory device according to the first embodiment, and FIGS. 2F and 2G are sectional views to explain a method of manufacturing a nonvolatile semiconductor memory device according to a modification of the first embodiment;

FIGS. 3A, 3B, 3C are sectional views to explain the method of manufacturing a nonvolatile semiconductor memory device following FIG. 2E;

FIG. 4 is a sectional view showing a modification of the first embodiment;

FIG. 5 is a sectional view of a nonvolatile semiconductor memory device according to a second embodiment; and

FIGS. 6A, 6B are sectional views to explain a part of the manufacturing processes in the second embodiment.

### DETAILED DESCRIPTION

In general, according to one embodiment, a nonvolatile semiconductor memory device includes a plurality of gate electrode structures formed on a semiconductor substrate and an insulating film which covers the gate electrode structures and contains an air gap. Each of the gate electrode structures includes a gate insulting film, a charge storage layer, an intermediary insulating film, and a control gate electrode. The control gate electrode includes a first control gate and a second control gate whose width is greater than that of the first control gate. The air gap is formed so as to be higher than a space between the control gate electrodes and than the control gate electrodes.

As memory elements have been miniaturized further, the width of a gate electrode structure has been decreasing in a NAND flash memory. Therefore, the volume of the control gate has been decreasing and the interconnection resistance of the control gate has been increasing. In addition, with the increasing miniaturization of memory elements, the coupling capacitance between memory elements also has been increasing. Therefore, the CR coefficient has been increasing, causing a delay in the propagation of a program voltage and a voltage drop, which has deteriorated the write and read characteristics.

To overcome those problems, the embodiment increases the width of the control gate electrode to increase the volume, thereby decreasing the interconnection resistance of the control gate electrode, and further provides control gates and an air gap between control gate electrodes, thereby decreasing the coupling capacitance between control gates. This makes it possible to decrease both the interconnection resistance and coupling capacitance, making the CR coefficient smaller, which prevents a delay in the propagation of a program voltage and a voltage drop and improves the write characteristic and the read characteristic.

Furthermore, when the width of the control gate electrode is increased to decrease the interconnection resistance of the control gate electrode, the distance between control gate electrodes is reduced, increasing an electric field. As a result, the break down voltage between the control gates drops. Since a high voltage is applied to the control gate selected in programming and a relatively low voltage is applied to the unselected control gate electrodes, when the break down voltage has dropped, the control gate electrodes may be short-circuited. In the embodiment, however, forming an air gap in order to cover the top of the control gate electrode increases the break down voltage.

Hereinafter, embodiments will be explained with reference to the accompanying drawings.

### First Embodiment

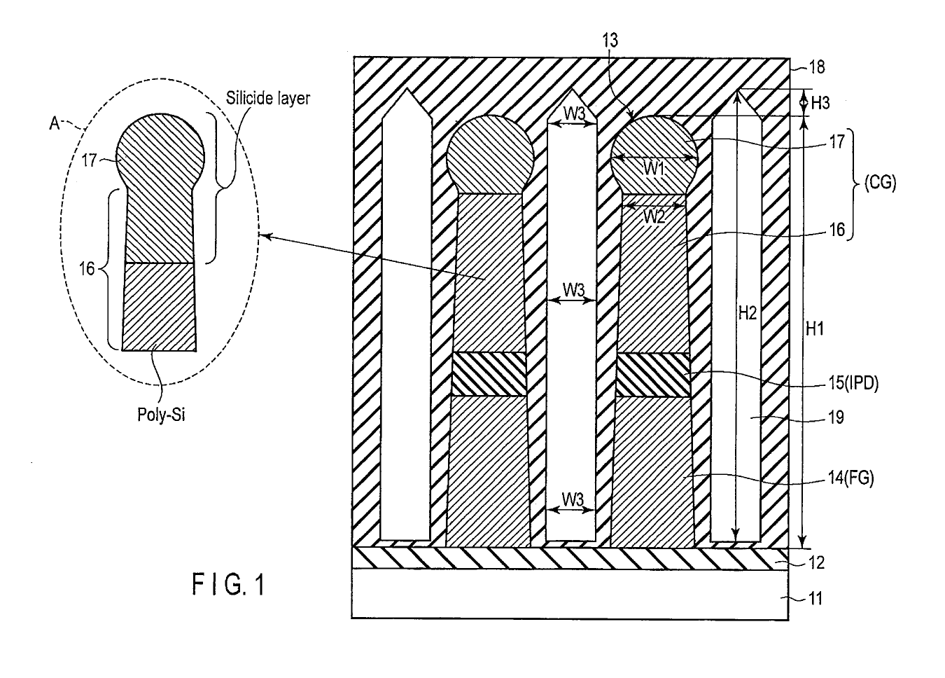

FIG. 1 shows an element structure of a NAND flash memory according to a first embodiment. The element structure of the first embodiment constitutes a memory cell transistor using a gate electrode structure 13 described later. In FIG. 1, source and drain diffused layers and others are not shown.

In FIG. 1, for example, on a silicon substrate 11, a gate oxide film (tunnel oxide film) 12 composed of, for example, a silicon oxide film, is formed. On the gate oxide 12, a gate electrode structure 13 is formed. That is, on the gate oxide film 12, a charge storage layer (FG) 14, an intermediary insulating film (IPD) 15, a control gate (CG) 16 are stacked one on top of another in that order. Each of the charge storage layer 14 and control gate 16 is composed of a polycide structure of polysilicon or polysilicon and a silicide layer, or of a silicide layer. The intermediary insulating film 15 is composed of, for example, an ONO film. If the control gate 16 has a polycide structure, it has the appearance shown by A in FIG. 1. On the control gate 16, a control gate electrode 17 composed of a silicide layer is formed. Width W1 of the control gate electrode 17 is set greater than width W2 of the top of the control gate 16, with the result that the control gate electrode has a larger volume than that of a conventional silicide layer. The control gate electrode 17 composed of a silicide layer includes a metallic element, such as cobalt or nickel. Hereinafter, the control gate 16 and control gate electrode 17 may be collectively called a control gate CG. That is, the control gate CG includes the control gate 16 and the control gate electrode 17 whose width is greater than that of the control gate 16.

The gate electrode structure 13 has, for example, a high aspect ratio because of the miniaturization of elements. The sidewalls of the charge storage layer 14, intermediary insulating film 15, and control gate 16 are tapered toward the top of the control gate 16 in order to gradually reduce the width. The tapered shape can increase the distance between adjacent control gates 16, enabling the coupling capacitance to be decreased and the break down voltage to be made higher. In addition, the bottom surface of the charge storage layer 14 can be made larger, enabling the channel length of the memory cell transistor to be made larger. As a result, the short channel characteristic of the memory cell transistor can be improved.

The gate electrode structure 13 including a control gate electrode 17 is covered with an insulating film 18. In the insulating film 18 between adjacent gate electrode structures 13 each of which includes a control gate electrode 17, an air gap 19 is made. Height H2 of the air gap 19 is set greater than height H1 of the gate electrode structure 13 including the control gate electrode 17 by height H3. That is, the air gap 19 is formed higher than a space between adjacent gate electrode structures 13 and than a space between adjacent control gate electrodes 17. Height H3 is, for example, not less than 10 nm, preferably not less than 5 nm. Setting the height to such a value makes it possible to reduce the electric field between adjacent control gates CGs, enabling short-circuiting between the control gate electrodes 17 to be prevented.

In addition, the air gap 19 has the width of a part corresponding to the lower part of the charge storage layer 14, the width of a part corresponding to the control gate 16, and the width near its vertex all set to almost W3.

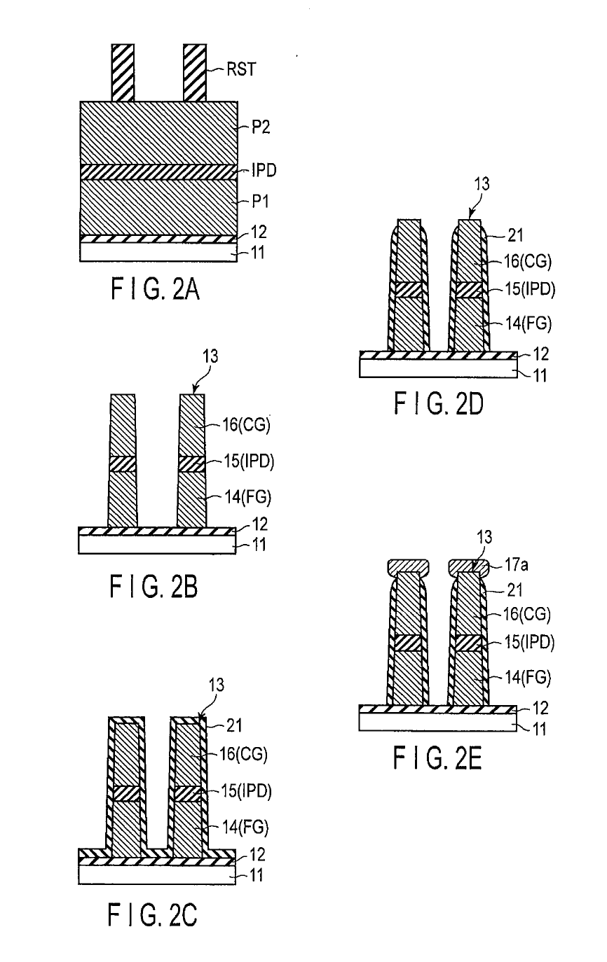

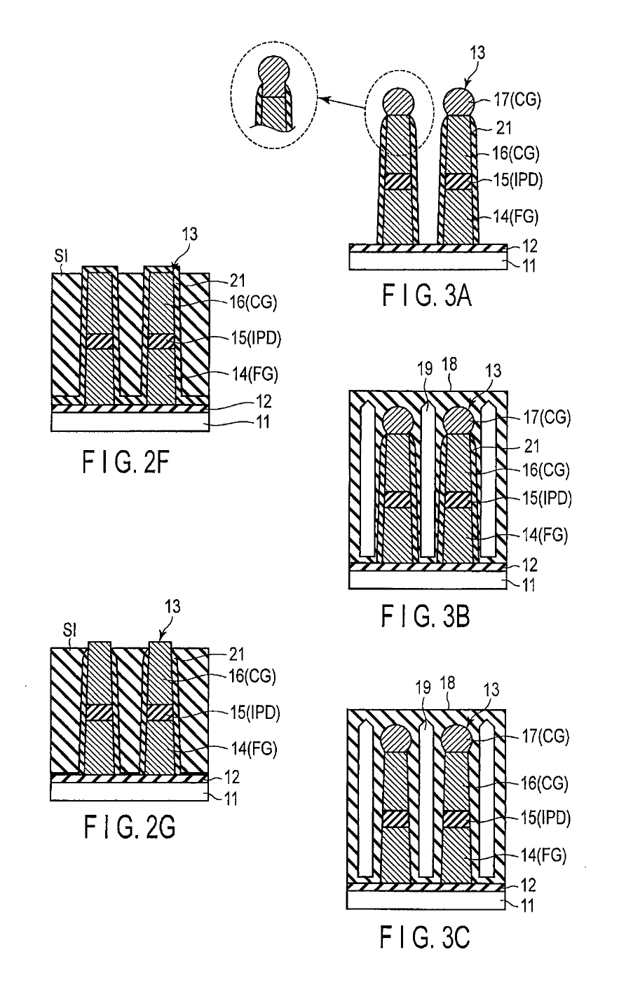

Next, a method of manufacturing the element structure will be explained with reference to FIGS. 2A to 2E and FIGS. 3A to 3C.

As shown in FIG. 2A, for example, on a silicon substrate 11, a gate oxide film 12 composed of a silicon oxide film is formed. On the gate oxide film 12, for example, a first polysilicon layer P1, an intermediary insulating film IPD composed of, for example, an ONO film and, for example, a second polysilicon film P2 are formed in that order. On the second polysilicon layer P2, a patterned resist film RST is formed. With the resist film RST as a mask, the second polysilicon layer P2, intermediary insulating film IPD, and first polysilicon layer P1 are etched sequentially.

As a result of this etching, a gate electrode structure 13 that has a charge storage layer 14, an intermediary insulating film 15, and a control gate stacked one on top of another is formed as shown in FIG. 2B. The gate electrode structure 13 has a tapered sidewall.

Next, as shown in FIG. 2C, for example, a silicon oxide film 21 is formed on the entire surface, with the result that the top face and sidewall of the gate electrode structure 13 are covered with the silicon oxide film 21.

Thereafter, as shown in FIG. 2D, the silicon oxide film 21 is subjected to anisotropic etching, with the result that at least the top face of the gate electrode structure 13 and the silicon oxide film 21 in the upper part of the sidewall are removed. As a result, the top of the gate electrode structure 13, that is, the top of the control gate 16, is exposed.

Next, as shown in FIG. 2E, a metallic film 17a, such as nickel or cobalt, that reacts with silicon is deposited on the top of the exposed control gate 16 by sputtering or the chemical vapor deposition (CVD) method. Therefore, the metallic film 17a is formed on the top of the exposed control gate 16.

Next, the metallic film 17a is subjected to heat treatment, forming silicide. In the silicide formation, the volume of the upper part of the control gate 16 is expanded as shown in FIG. 3A, with the result that a control gate electrode 17 whose width is greater than the top of the control gate 17 is formed.

Thereafter, as shown in FIG. 3B, the gate electrode structure 13 including the control gate electrode 17 is covered with an insulating film 18. The insulating film 18 is, for example, a silicon oxide film formed by plasma CVD techniques using, for example, silane as raw material gas.

The insulating film 18 is formed under the condition that the growth rate in the longitudinal direction of the film (the direction in which the charge storage layer 14 and control gate electrode 17 are stacked one on top of the other) is faster than that in the lateral direction of the film (the direction in which the control gates 17 are adjacent to one another). Therefore, the space between gate electrode structures 13 including adjacent control gate electrodes 17 is not filled completely with the insulating film 18, creating an air gap 19. In addition, since the growth rate in the longitudinal direction of the insulating film 18 is set greater than the growth rate in the lateral direction, the vertex of the air gap 19 is formed in a position higher than the control gate electrode 17. Height H3 from the control gate electrode 17 to the vertex is as described above. The condition that the growth rate in the longitudinal direction of the film is faster than that in the lateral direction is set by, for example, the flow rate of raw material gas and processing temperature. If the insulating film 18 and silicon oxide film 21 are made of the same material (for example, a silicon oxide film), the boundary between them is unclear and is shaped as shown in FIG. 3C. After this, for example, heat treatment is performed, which completes an element structure as shown in FIG. 1.

The manufacturing method is not limited to the above example and may be modified as follows. For example, following FIG. 2C, a sacrificial film SI composed of, for example, a silicon nitride film is deposited. The top face of the sacrificial film SI is made lower than the top of the gate electrode structure 13 by etching (FIG. 2F). As a result, the top of the gate electrode structure 13 covered with the silicon oxide film 21 is exposed in the sacrificial film. With the sacrificial film as an etching stopper, the silicon oxide film 21 is etched, with the result that the top of the control gate 16 is exposed (FIG. 2G). Then, the top of the silicon oxide film 21 may be etched by an anisotropic etching. Thereafter, a metallic film 17a that reacts with silicon is formed on the exposed control gate 16. After this, heat treatment is performed to form a silicide film as a control gate electrode 17. The silicide formation is performed not only upward and laterally but also downward. However, on the underside of the control gate 16, the silicon oxide film 21 has been formed, with the result that the control gate 16 is turned into silicide so as to expand upward. As a result, the metallic film 17a is formed on a part of the control gate 16 not covered with the silicon oxide film 21. Then, the sacrificial film is removed, forming a structure a shown in FIG. 3A. Hereinafter, the same manufacturing processes as described above are performed, forming a structure as shown in FIG. 3C. Such a manufacturing method may be applied.

With the first embodiment, the control gate electrode 17 composed of a silicide layer whose width is greater than that of the control gate 16 is provided on the top of the control gate 16. Therefore, the interconnection resistance of the control gate CG can be decreased as compared with a conventional equivalent. In addition, the air gap 19 is made between gate electrode structures 13 each including the control gate electrode 17. Therefore, the permittivity of the space between adjacent control gate electrodes 17 can be made equal to the permittivity of vacuum (=1) smaller than the permittivity of a silicon oxide film (=almost 3.9). As a result, not only the coupling capacitance between control gates 16 but also the coupling capacitance between control gate electrodes 17 can be decreased. Accordingly, since both the interconnection resistance and the capacitance of control gate CG can be decreased, the CR coefficient can be made smaller, preventing a delay in the propagation of a program voltage and a voltage drop, which enables a higher-speed operation and improves the write characteristic.

In addition, the position of the vertex of the air gap 19 is set higher than the top face of the control gate electrode 17. Therefore, even if the distance between adjacent control gate electrodes 17 is reduced as a result of the miniaturization of elements, the electric field can also be reduced, enabling the short-circuiting between control gate electrodes 17 to be prevented. Furthermore, even an electric field that reaches higher than the top face of the control gate electrode 17 can be reduced, which further improves the write characteristic or the like.

(Modification)

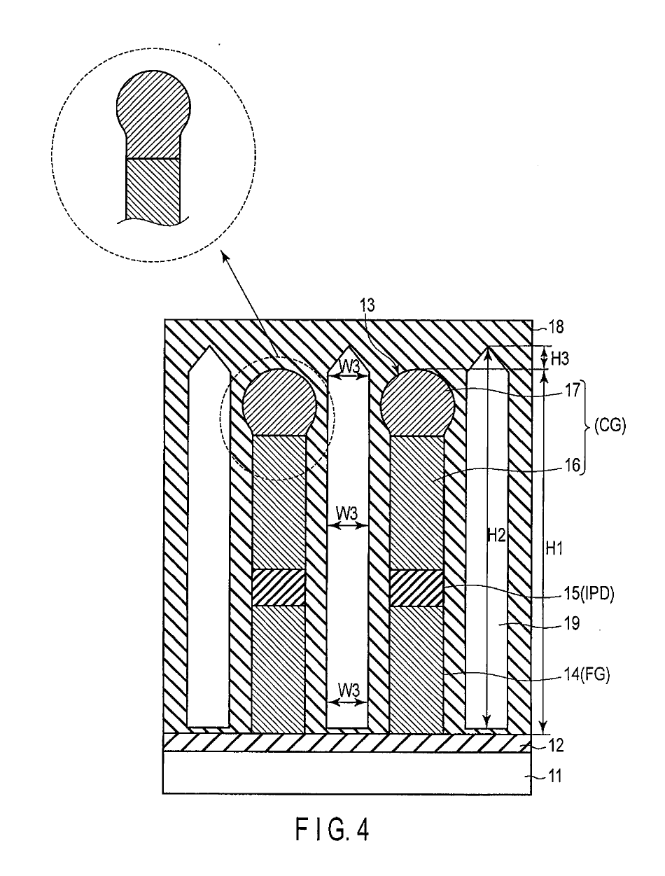

FIG. 4 shows a modification of the first embodiment. FIG. 4 shows a case where the first embodiment is applied to a NAND flash memory whose distance between adjacent gate electrode structures 13 is greater than that in the first embodiment.

When the distance between gate electrode structures 13 is greater than that in the first embodiment, the coupling capacitance between control gates CG is lower than that in the first embodiment. Therefore, the control gate 16 need not be tapered in order to make its upper part narrower. That is, the sidewall of the gate electrode structure 13 need not be tapered and may be shaped like a vertical sidewall.

In addition, an air gap 19 is made adjacent to the gate electrode structure 13 including the control gate electrode 17 in order to set the position of the vertex of the air gap 19 higher than the top surface of the control gate electrode 17, improving the break down voltage of the spacing between adjacent control gate electrodes 17, which produces the same effect as in the first embodiment. Moreover, the cross-sectional area of the control gate 16 can be made larger, enabling the interconnection resistance of the control gate CG to be made lower.

### Second Embodiment

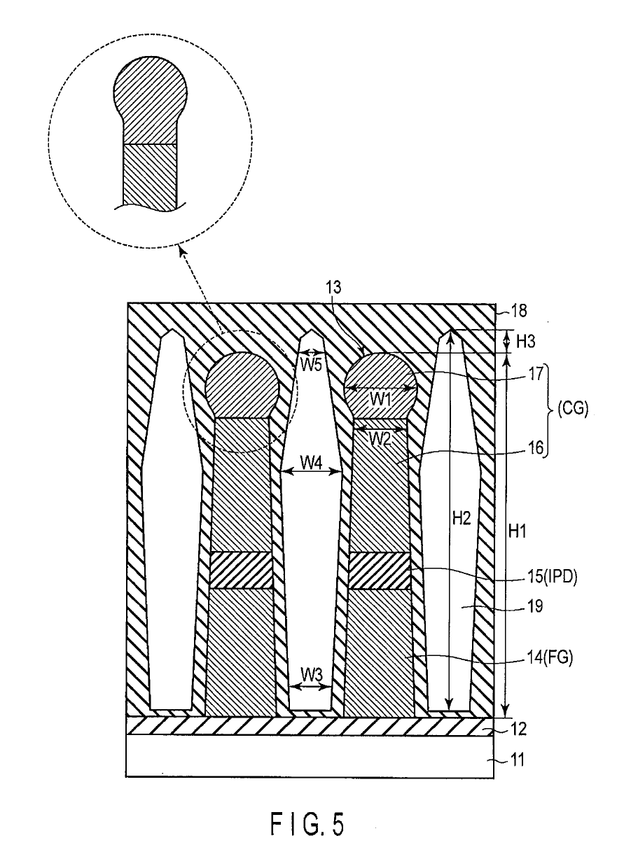

FIG. 5 shows an element structure according to a second embodiment. The second embodiment differs from the first embodiment in the shape of the air gap 19. The element structure of the second embodiment is suitable for the miniaturization of elements. In the second embodiment, the same parts as those of the first embodiment are indicated by the same reference numerals.

When gate electrode structures 13 are miniaturized more than those in the first embodiment, the coupling capacitance between adjacent control gates 16 increases more than in the first embodiment. In addition, the aspect ratio of the gate electrode structure 13 increases, making the processing of the gate electrode structure 13 more difficult.

Therefore, in the second embodiment, the gate electrode structure 13 has a tapered sidewall as in the first embodiment, making the distance between adjacent control gates 16 longer than the distance between adjacent charge storage layers 14 to decrease the coupling capacitance between adjacent control gates 16. With the tapered sidewall of the gate electrode structure 13, the processing becomes easier even if the aspect ratio is much higher than in the first embodiment.

In the second embodiment, on the top of the control gate 16, a control gate electrode 17 is formed as in the first embodiment. Width W1 of the control gate electrode 17 is set greater than width W2 of the top of the control gate 16, increasing the volume, which decreases the interconnection resistance of the control gate CG more than in a conventional equivalent.

The vertex of an air gap 19 made between gate electrode structures 13 including adjacent control gates 17 is set higher than the position of the top face of the control gate electrode 17. That is, as in the first embodiment, height H2 of the air gap 19 is set greater than height H1 of the gate electrode structure 13 including the control gate electrode 17 by height H3. Height H3 is, for example, not less than 10 nm, preferably not less than 5 nm.

Width W3 of a part corresponding to the lower part of the air gap 19 (the lower part of the charge storage layer 14) is less than width W4 corresponding to almost a middle part of the control gate 16. Width W5 of a part of the air gap 19 corresponding to a position higher than the top face of the control gate electrode 17 is set to be less than width W3 of the lower part. That is, the relationship between these widths is expressed as W5<W3<W4. Making width W4 of the part corresponding to the middle part of the control gate 16 greater than the rest enables the coupling capacitance to be further decreased. A shape of the vertex of the air gap 19 is sharp and a sectional shape of the air gap 19 along the gate electrode structure is similar to a pentagon.

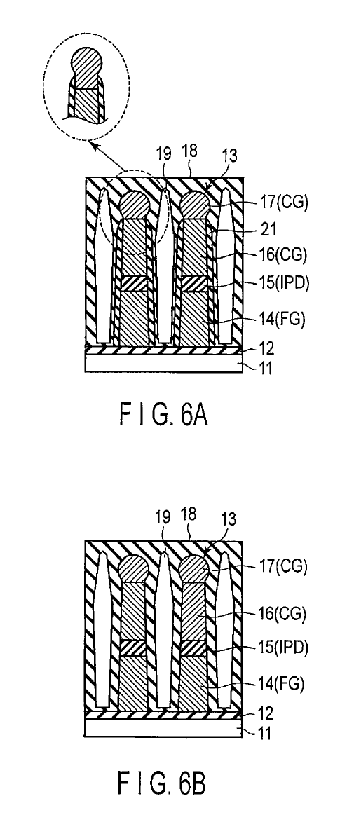

FIGS. 6A and 6B show a part of the processes of the manufacturing method according to the second embodiment. The same parts as those of the first embodiment are indicated by the same reference numerals. In the second embodiment, the manufacturing processes performed earlier than FIG. 6A are the same as the manufacturing processes of the first embodiment shown in FIGS. 2A to 2E and FIG. 3A.

FIG. 6A shows a manufacturing process following FIG. 3A. That is, FIG. 6A shows the process of forming an insulating film 18. The insulating film 18 is formed by plasma CVD techniques using, for example, silane as raw material gas. The insulating film 18 is formed under the condition that the growth rate in the longitudinal direction of the film is greater than that in the lateral direction of the film. The film forming condition is controlled by, for example, the flow rate of raw material gas and processing temperature.

In the second embodiment, memory elements are miniaturized more than in the first embodiment. At the start of the formation of an insulating film 18, the insulating film 18 depends on the shape of the gate electrode structure 13 and grows along the tapered sidewall of the gate electrode structure 13. The insulating film 18 grows almost up to the central part of the control gate 16 in height. The growth rate of the insulating film 18 in the vertical direction on a gate insulating film between gate electrode structures 13 is low because it is difficult for raw material gas to reach the insulating film 18. That is, the growth of the insulating film 18 in the lateral direction is dominant, with the result that the insulting film 18 grows along the tapered sidewall of the gate electrode structure 13. Then, the width of the air gap 19 is reduced under the influence of a projection of the control gate electrode 17. However, since the growth of the insulating film 18 in the lateral direction is slow, the air gap 19 will never terminate at a part adjacent to the control gate electrode 17. Moreover, above the central part of the control gate electrode 17 (a part where the space between the control gate electrodes 17 becomes least), the growth of the insulating film 18 in the lateral direction is slow and the growth in the lateral direction is fast. Therefore, the vertex of the air gap 19 terminates in a position higher than the gate electrode 17. At the time when the vertex of the air gap. 19 is formed, the air gap 19 is completed. At this time, the growth of the insulating film in the vertical and lateral directions in the air gap 19 is stopped. In a position higher than the vertex of the air gap 19, deposition is performed so that the insulating film 18 may grow in the vertical direction. If the insulating film 18 and silicon oxide film 21 are made of the same material (for example, a silicon oxide film), the boundary between them is unclear and a shape as shown in FIG. 6B is obtained.

After this, for example, heat treatment is performed, which completes an element structure as shown in FIG. 5.

With the second embodiment, the control gate electrode 17 whose width is greater than that of the control gate 16 is formed on the gate electrode structure 13 with a tapered sidewall, increasing the volume. Therefore, the interconnection resistance of the control gate CG can be decreased as compared with a conventional equivalent.

In addition, the air gap 19 is made between adjacent gate electrode structures 13 each including the control gate electrode 17. Therefore, the permittivity of the space between adjacent control gate electrodes 17 can be made equal to the permittivity of vacuum (=1). The width of the air gap 19 corresponding to the control gate 16 is made greater than the rest. Accordingly, the coupling capacitance between control gates 16 can be reduced remarkably. Therefore, since both the interconnection resistance and the capacitance of control gate CG can be decreased, the CR coefficient can be made smaller even if elements have been miniaturized, preventing a delay in the propagation of a program voltage and a voltage drop, which enables a higher-speed operation and improves the write characteristic.

In addition, the position of the vertex of the air gap 19 is set higher than the top face of the control gate electrode 17. Therefore, even if the distance between adjacent control gate electrodes 17 is reduced as a result of the miniaturization of elements, the electric field can also be reduced, enabling the short-circuiting between control gate electrodes to be prevented.

While in the first and second embodiments, a charge-storage cell structure with a charge storage layer 14 has been explained. However, the embodiments may be applied to a cell structure that traps charge, such as a MONOS-structure cell. At this time, the charge storage layer 14 may be composed of insulating film with charge trap (e,q, SiN) and the intermediary insulating film 15 may composed of AlO or HfAlO. That is, a memory element has only to have a charge storage layer that has the function of storing charge and is not limited to the use of the charge storage layer 14.

In addition, although the air gap 19 is formed from a part corresponding to the charge storage layer 14, the embodiments are not limited to this. The air gap 19 has only to be formed from a part corresponding to at least the control gate 16 and control gate electrode 17 and above the control gate electrode 17.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a plurality of gate electrode structures formed on a semiconductor substrate each of which including a gate insulting film, a charge storage layer, an intermediary insulating film, and a control gate electrode, the control gate electrode including a first control gate and a second control gate whose width is greater than that of the first control gate; and
an insulating film which covers the gate electrode structures and has an air gap in it, the air gap being formed so as to be higher than a space between the control gate electrodes and than the control gate electrodes.

2. The device according to claim 1, wherein the gate electrode structures each have a tapered sidewall where the width of the first control gate is less than that of the charge storage layer.

3. The device according to claim 2, wherein the width of the air gap is greatest at a part corresponding to the first control gate.

4. The device according to claim 3, wherein the height of the air gap is greater than that of each of the gate electrode structures.

5. The device according to claim 1, wherein the second control gates of the gate electrode structures are made of silicide.

6. The device according to claim 5, wherein a part of each of the first control gates of the gate electrode structures is made of silicide.

7. A method of manufacturing a nonvolatile semiconductor memory device, the method comprising:
forming a plurality of gate electrode structures on a semiconductor substrate, each of which has a gate insulating film, a charge storage layer, an intermediary insulating film, and a control gate stacked one on top of another in that order on the semiconductor substrate;
forming a metallic layer on the control gate of each of the gate electrode structures;
forming silicide by heat treatment in order to make the upper part of the control gate wider; and
forming an insulating film with an air gap in it under a film formation condition that a growth rate in a longitudinal direction is faster than that in a lateral direction, the air gap being higher than at least a space between the control gates and than the control gate electrodes.

8. The method according to claim 7, wherein the gate electrode structures each have a tapered sidewall where the width of the lower part of the control gate is less than that of the charge storage layer.

9. The method according to claim 7, wherein the width of the air gap is greatest at a part corresponding to the first control gate.

10. The method according to claim 9, wherein the height of the air gap is greater than that of each of the gate electrode structures.

11. The method according to claim 7, wherein after forming the gate electrode structures, an insulating film is formed on upper surfaces and side surfaces of the gate electrode structures.

12. The method according to claim 11, wherein at least the upper surfaces and upper portions of side surfaces of the gate electrode structures are removed.

13. The device according to claim 3, further comprising
an air gap formed between charge storage layers of the gate electrode structures, and width of the air gap formed above the control gate electrode is narrower than that of the air gap formed between the charge storage layers of the gate electrode structures.

14. The device according to claim 1, a shape of the air gap is a pentagon.
